(19) United States
(12) Patent Application Publication
(10) Pub. No.: US 2008/0064215 A1
(43) Pub. Date: Mar. 13, 2008

(54) METHOD OF FABRICATING A SEMICONDUCTOR PACKAGE

(75) Inventors: Min-ok NA, Cheonan-si (KR); Hak-kyoon BYUN, Asan-si (KR); Hyun-jung SONG, Yongin-si (KR); Chi-young LEE, Hwseong-si (KR); Tae-eun KIM, Ansan-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/835,460

(22) Filed: Aug. 8, 2007

(30) Foreign Application Priority Data
Sep. 11, 2006 (KR) 10-2006-0087456

(51) Int. Cl. H01L 21/311

(52) U.S. Cl. 438/702; 257/E21.249

(57) ABSTRACT

In one aspect, a method of manufacturing a semiconductor package includes providing a semiconductor substrate which includes a plurality of semiconductor chips and a scribe lane defined between the semiconductor chips, forming a trench within the scribe lane, filling the trench with a photolytic polymer, grinding a back side of the semiconductor substrate including the photolytic polymer within the trench, and radiating light onto a front surface of the semiconductor substrate to dissolve the photolytic polymer.

### CROSS-REFERENCE TO RELATED PATENT APPLICATION

A claim of priority is made to Korean Patent Application No. 10-2006-0087456, filed Sep. 11, 2006, in the Korean Intellectual Property Office, the disclosure of which is incorporated herein in its entirety by reference.

### BACKGROUND OF THE INVENTION

1. Field of the Invention

The present invention relates to a method of fabricating a semiconductor package, and more particularly, to a method of fabricating a semiconductor package having a relatively thin semiconductor chip.

2. Description of the Related Art

Semiconductor chips having thicknesses of 100 μm or less are increasing used in a variety of mobile products, such as System in Packages (SiP), IC cards and RFID tags. Since the diameter of wafers used to fabricate the chips has increased (e.g., towards 300 mm), it is generally necessary to conduct a difficult thinning process during manufacture to decrease the thickness of the finally formed chips.

Generally, the thinning process entails backside grinding of the wafer. Thereafter, a scribe lane is formed by sawing to individually separate the semiconductor chips formed on the wafer. Each separated semiconductor chip is then mounted onto a circuit substrate, thereby fabricating a semiconductor package.

However, sawing of the scribe lane after the backside grinding process can result in chipping or cracking of semiconductor chip. Such chipping or cracking adversely impact characteristics of the chip. For example, an over stiffness of the semiconductor chip may deteriorate.

### SUMMARY OF THE INVENTION

According to an aspect of the present invention, a method of manufacturing a semiconductor package includes providing a semiconductor substrate which includes a plurality of semiconductor chips and a scribe lane defined between the semiconductor chips, forming a trench within the scribe lane, filling the trench with a photolytic polymer, grinding a back side of the semiconductor substrate including the photolytic polymer within the trench, and radiating light onto a front surface of the semiconductor substrate to dissolve the photolytic polymer.

According to another aspect of the present invention, a method of manufacturing a semiconductor package includes providing a semiconductor substrate which includes a plurality of semiconductor chips and a scribe lane defined between the semiconductor chips, forming a trench within the scribe lane, disposing a mask on a front surface of the semiconductor substrate which includes an opening that exposes the trench, filling the trench with a photolytic polymer via the opening in the mask, removing the mask to expose the front surface of the semiconductor substrate, grinding a back side of the semiconductor substrate including the photolytic polymer within the trench, attaching a mounting tape on the ground back side of the semiconductor substrate, and radiating light onto the front surface of the semiconductor substrate to dissolve the photolytic polymer.

### BRIEF DESCRIPTION OF THE DRAWINGS

The above and other features and advantages of the present invention will become readily apparent from the detailed description that follows, with reference to the accompanying drawings, in which:

FIG. 1 is a plan view illustrating a semiconductor substrate which may be utilized in an embodiment of the present invention; and

FIGS. 2A through 2G are sectional views for describing a method of fabricating a thin semiconductor package according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to those skilled in the art. Like reference numerals in the drawings denote like elements, and thus their description will not be repeated.

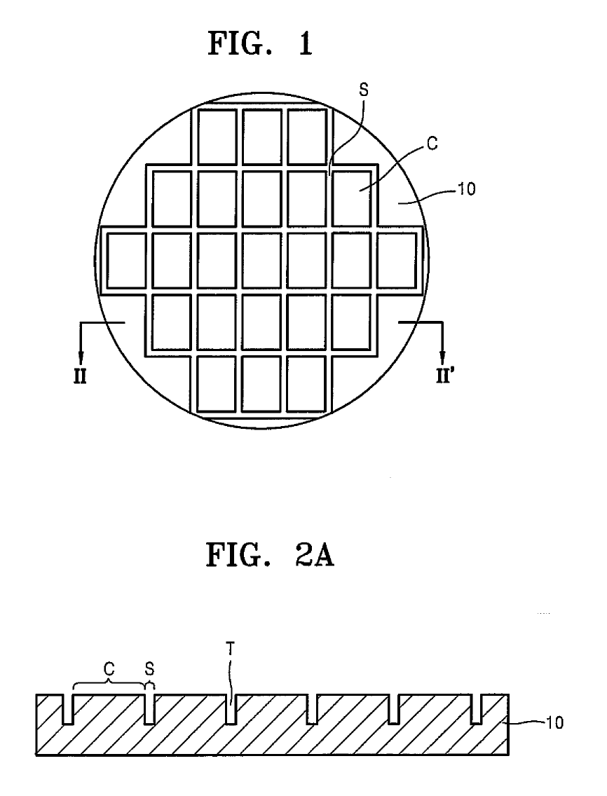

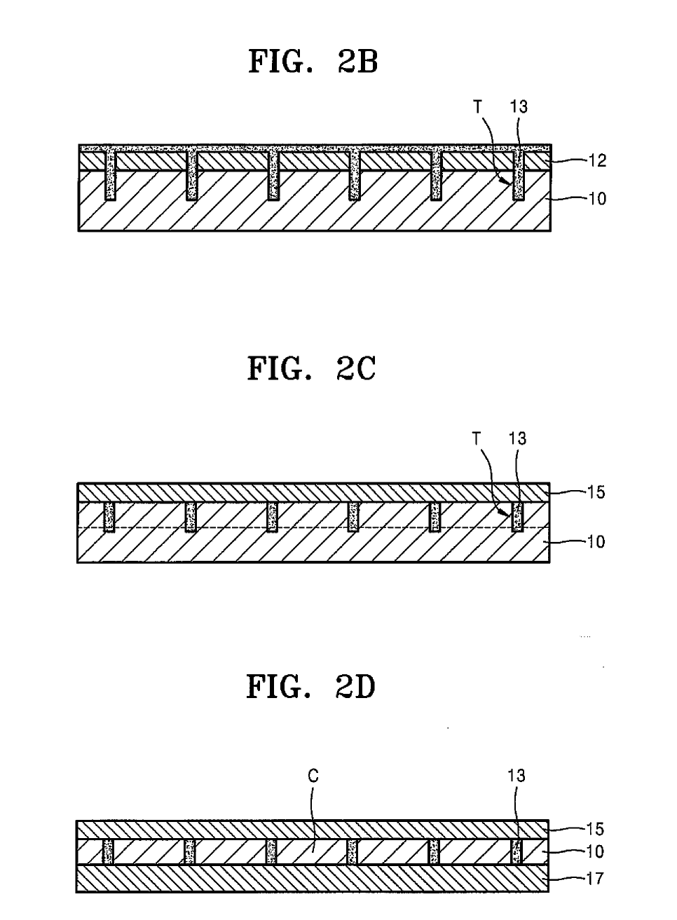

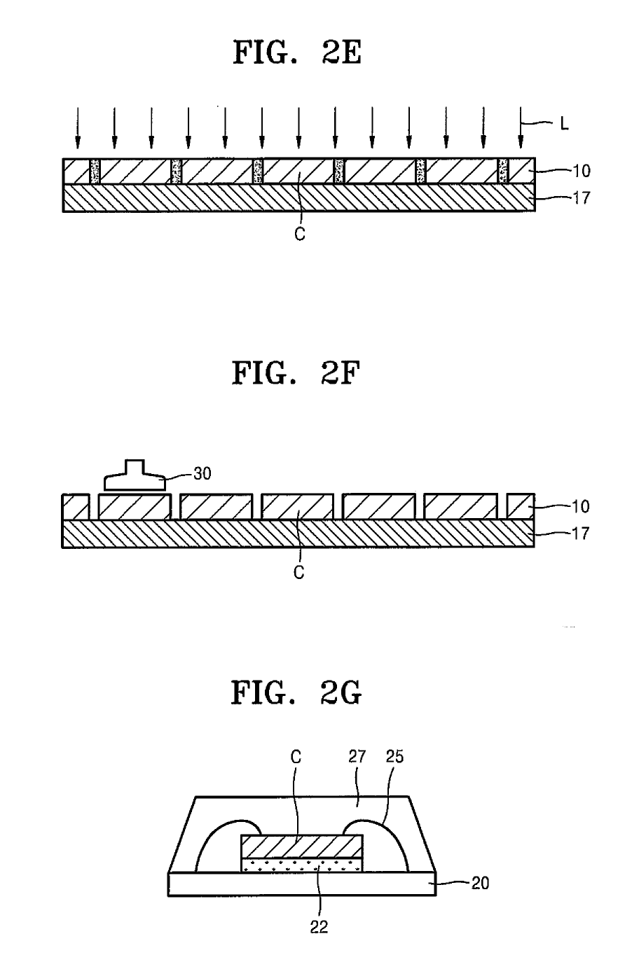

FIG. 1 is a plan view illustrating a semiconductor substrate which may be utilized in an embodiment of the present invention. FIGS. 2A through 2G are sectional views for use in describing a method of fabricating a thin semiconductor package according to an embodiment of the present invention. In particular, FIG. 2A is a sectional view taken along a line II-II′ of FIG. 1.

Referring to FIGS. 1 and 2A, a semiconductor substrate 10 includes a plurality of semiconductor chips C formed with semiconductor devices, and scribe lanes S located between the plurality of semiconductor chips C. Since the semiconductor chips C are arranged in row and column directions, the scribe lanes S intersect one another to define crisscross pattern.

By etching the semiconductor substrate 10, a trench T is defined within and along the scribe lanes S. The semiconductor substrate 10 may, for example, be etched using a diamond blade or a laser.

Referring to FIG. 2B, a mask 12 is disposed on the substrate 10. The mask includes openings which expose the trench T along the scribe lanes S.

The openings in the mask 12 and the trench T is then filled with a photolytic polymer to define a photolytic polymer layer 13. The photolytic polymer layer 13 may, for example, be formed by roller coating. In the illustrated example of FIG. 2B, the photolytic polymer layer is also be formed on an upper surface of the mask 12.

The photolytic polymer may include polymer having a photosensitive functional group. More specifically, an ethylene•carbonmonoxide(CO) copolymer, a vinyl keton copolymer or a combination of these materials may be included. The photolytic polymer may include photo-sensitizer as an additive. The photosensitizer may be an aromatic keton group, a metal composite material that can form radicals by light, or a combination of these materials. The aromatic keton group may include benzophenone, acetophenone and anthraquinone.

Referring to FIG. 2C, the mask 12 and the photolytic polymer within the openings of the mask 12 are removed to expose a front surface of the substrate 10. As a result, the photolytic polymer layer 13 remains within the trench T along the scribe lanes S.

Thereafter, a protection tape 15 is attached on the front surface of the substrate 10. The protection tape 15 shields the front surface of the substrate 10 during back grinding (described later).

Referring to FIG. 2D, a back side of the substrate 10 is ground until the trench T is partially etched (i.e., until the photolytic polymer layer 13 is exposed). For example, the back side of the substrate 10 is ground until reaching a position shown by the dot-lined of FIG. 2C. As a result, the semiconductor chips C are connected to each other by the protection tape 15, and the photolytic polymer layer 13 is positioned between the semiconductor chips C. Since the semiconductor chips C remain connected and spaced from each other by the photolytic polymer layer 13, misalignment between the semiconductor chips C during the back grinding process is prevented. Subsequently, a mounting tape 17 is attached on the back side of the back-ground substrate 10.

Referring to FIG. 2E, the protection tape 15 is detached to expose the front surface of the substrate 10. Thereafter, light L is radiated on the front surface of the substrate 10. The light L may be ultraviolet rays having a wavelength range of 290 nm˜315 nm.

Referring to FIG. 2F, the photolytic polymer is dissolved by the radiation of the light L. As a result, the semiconductor chips C are separated from each other under the state of being attached onto the mounting tape 17. Therefore, the semiconductor chips C can be easily separated without performing additional sawing after back grinding of the substrate 10. Consequently, the occurrence of chipping or cracking at an edge of the semiconductor chips C can be prevented.

Subsequently, the substrate 10 may be cleansed. The cleansing of the substrate 10 may be performed by jetting distilled water onto the substrate 10. Thus, the photolytic polymer is dissolved and completely removed.

Referring to FIG. 2G, any one of the semiconductor chips C is extracted from the mounting tape 17 using an apparatus 30 of FIG. 2F such as vacuum tweezers. Then, a bonding film 22 is attached on the back side of the extracted semiconductor chip C, which is attached on an circuit substrate 20. Thereafter, a terminal pad (not shown) of the semiconductor chip C is electrically connected to a terminal pad (not shown) of the circuit substrate 20 using wires 25. Thereafter, a molding layer 27 for embedding the terminal pads and the semiconductor chips C is formed to complete the semiconductor package. However, the method of manufacturing the semiconductor package using the semiconductor chip C is not restricted to the example of FIG. 2G.

According to the present invention as described above, semiconductor chips can be easily separated without requiring additional sawing after back grinding of a semiconductor substrate. Therefore, the occurrence of chipping or cracking at an edge of the semiconductor chips can be prevented. Consequently, a semiconductor package having a semiconductor chip of relatively small thickness can be readily manufactured.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a semiconductor package, comprising:
providing a semiconductor substrate which includes a plurality of semiconductor chips and a scribe lane defined between the semiconductor chips;
forming a trench within the scribe lane;
filling the trench with a photolytic polymer;
grinding a back side of the semiconductor substrate including the photolytic polymer within the trench; and
radiating light onto a front surface of the semiconductor substrate to dissolve the photolytic polymer.

2. The method of claim 1, further comprising, prior to filling the trench with the photolytic polymer, disposing a mask on the substrate which includes an opening that exposes the trench, wherein the trench is then filled with the photolytic polymer via the opening in the mask.

3. The method of claim 1, further comprising cleansing the semiconductor substrate after radiating the light on the front surface of the semiconductor substrate.

4. The method of claim 1, wherein the photolytic polymer comprises an ethylene•carbonmonoxide(CO) copolymer, a vinyl keton copolymer or a combination of these materials.

5. The method of claim 1, wherein the photolytic polymer comprises an aromatic group keton, a metal composite material that can form radicals by light, or a combination of these materials.

6. The method of claim 1, further comprising attaching a protection tape on the front surface of the semiconductor substrate having the trench filled with photolytic polymer before grinding the back side of the semiconductor substrate.

7. The method of claim 1, further comprising attaching a mounting tape on the back side of the semiconductor substrate after grinding the back side and before radiating the light on the front surface of the semiconductor substrate.

8. A method of manufacturing a semiconductor package comprising:
providing a semiconductor substrate which includes a plurality of semiconductor chips and a scribe lane defined between the semiconductor chips;
forming a trench within the scribe lane;
disposing a mask on a front surface of the semiconductor substrate which includes an opening that exposes the trench;
filling the trench with a photolytic polymer via the opening in the mask;
removing the mask to expose the front surface of the semiconductor substrate;
grinding a back side of the semiconductor substrate including the photolytic polymer within the trench;
attaching a mounting tape on the ground back side of the semiconductor substrate; and
radiating light onto the front surface of the semiconductor substrate to dissolve the photolytic polymer.

9. The method of claim 8, further comprising cleansing the semiconductor substrate after radiating the light on the front surface of the semiconductor substrate;

10. The method of claim 8, wherein the photolytic polymer comprises an ethylene•carbonmonoxide(CO) copolymer, a vinyl keton copolymer or a combination of these materials.

11. The method of claim 8, wherein the photolytic polymer comprises an aromatic group keton, a metal composite material that can form radicals by light, or a combination of these materials.
